(19) United States
(12) Patent Application Publication
(10) Pub. No.: US 2008/0277726 A1
(43) Pub. Date: Nov. 13, 2008

(54) Devices with Metal Gate, High-k Dielectric, and Butted Electrodes

(76) Inventors: Bruce B. Doris, Brewster, NY (US); Eduard Albert Cartier, New York, NY (US); Barry Paul Linder, Hastings-on-Hudson, NY (US); Vijay Narayanan, New York, NY (US); Vamsi Paruchuri, New York, NY (US); Mark Todhunter Robson, Danbury, CT (US); Michelle L. Steen, Danbury, CT (US); Ying Zhang, Yorktwon Heights, NY (US)

Correspondence Address: INNOVATION INTERFACE, LLC, 303 TABER AVENUE, PROVIDENCE, RI, 02906, US

(21) Appl. No.: 11/745,994

(22) Filed: May 8, 2007

(51) Int. Cl. H01L 27/01; H01L 21/8238

(52) U.S. Cl. 257/351; 438/211; 257/E27.114; 257/E21.632

(57) ABSTRACT

FET device structures are disclosed with the PFET and NFET devices having high-k dielectric gate insulators and metal containing gates. The metal layers of the gates in both the NFET and PFET devices have been fabricated from a single common metal layer. As a consequence of using a single layer of metal for the gates of both type of devices, the terminal electrodes of NFETs and PFETs can be butted to each other in direct physical contact. The FET device structures further contain stressed device channels, and gates with effective workfunctions of n⁺ Si and p⁺ Si values.

### FIELD OF THE INVENTION

The present invention relates to high performance electronic circuits. In particular, it relates to structures having high-k containing gate dielectrics, and metal containing gates, where the gate metal is the same for NFET and PFET devices. The invention also relates to increasing the density of such circuits.

### BACKGROUND OF THE INVENTION

Today's integrated circuits include a vast number of devices. Smaller devices and shrinking ground rules are the key to enhance performance and to reduce cost. As FET (Field-Effect-Transistor) devices are being scaled down, the technology becomes more complex, and changes in device structures and new fabrication methods are needed to maintain the expected performance enhancement from one generation of devices to the next. The mainstay material of microelectronics is silicon (Si), or more broadly, Si based materials. One such Si based material of importance for microelectronics is the silicon-germanium (SiGe) alloy. The devices in the embodiments of the present disclosure are typically part of the art of single crystal Si based material device technology.

There is a great difficulty in maintaining performance improvements in devices of deeply submicron generations. Therefore, methods for improving performance without scaling down have become of interest. There is a promising avenue toward higher gate dielectric capacitance without having to make the gate dielectric actually thinner. This approach involves the use of so called high-k materials. The dielectric constant of such materials is significantly higher than that of SiO₂, which is about 3.9. A high-k material may physically be significantly thicker than oxide, and still have a lower equivalent oxide thickness (EOT) value. The EOT, a concept known in the art, refers to the thickness of such an SiO₂ layer which has the same capacitance per unit area as the insulator layer in question. In today state of the art FET devices, one is aiming at an EOT of below 2 nm, and preferably below 1 nm.

Device performance is also enhanced by the use of metal gates. The depletion region in the poly-Si next to the gate insulator can become an obstacle in increasing gate-to-channel capacitance. The solution is to use a metal gate. Metal gates also assure good conductivity along the width direction of the devices, reducing the danger of possible RC delays in the gate.

High performance small FET devices are in need of precise threshold voltage control. As operating voltage decreases, to below 2V, threshold voltages also have to decrease, and threshold variation becomes less tolerable. Every new element, such as a different gate dielectric, or a different gate material, influences the threshold voltage. Sometimes such influences are detrimental for achieving the desired threshold voltage values. Any technique which can affect the threshold voltage, without other effects on the devices is a useful one. One such technique, available when high-k dielectrics are present in a gate insulator, is the exposure of the gate dielectric to oxygen. A high-k material upon exposure to oxygen lowers the PFET threshold and increases the NFET threshold. Such an effect has already been reported, for instance: “2005 Symposium on VLSI Technology Digest of Technical Papers, Pg. 230, by E. Cartier”. Unfortunately, shifting the threshold of both PFET and NFET devices simultaneously, may not easily lead to threshold values in an acceptable tight range for in CMOS circuits. There is great need for a structure and a technique in which the threshold of one type of device can be independently adjusted without altering the threshold of the other type of device.

In enhancing FET performance a general approach is to stress tensilely or compressively the device channels. One prefers to have NFET device channel to be tensilely stressed, while the PFET device channel to be compressively stressed. It would be desirably combine the threshold adjusting features of the high-k dielectric and metal gate with the stressing of the device channels.

Beyond FET performance another aspect of interest and usefulness is the density of circuits. Generally, to increase density the art uses butted device electrodes, where the electrodes of NFET and PFET devices are in direct physical contact, without an intervening isolation structure. To date there are no high performance FET circuits with metal gates, high-k gate dielectrics, and butted electrodes.

### SUMMARY OF THE INVENTION

In view of the discussed difficulties, embodiments of the present invention discloses a circuit structure which includes at least one NFET and at least one PFET device. The NFET includes an n-channel hosted in a single crystal Si based material, a first gate stack including a first layer of the gate metal, and a cap layer, a first gate insulator including a first high-k dielectric, where the first high-k dielectric is in direct contact with the cap layer. The NFET further includes NFET electrodes, including a first electrode, adjoining the n-channel, and capable of being in electrical continuity with the n-channel. The PFET includes a p-channel hosted in the single crystal Si based material, a second gate stack including a second layer of the gate metal, a second gate insulator including a second high-k dielectric, where the second high-k dielectric is in direct contact with the second layer of the gate metal. The PFET further includes PFET electrodes, including a second electrode, adjoining the p-channel, and capable of being in electrical continuity with the p-channel. Furthermore, the first electrode and the second electrode are butted against one another in direct physical contact.

The circuit structure may further include a first dielectric layer overlaying the first gate stack and at least portions of the NFET electrodes, where the first dielectric layer and the n-channel are in tensile stress, where the tensile stress is imparted by the first dielectric layer onto the n-channel, and further includes a second dielectric layer overlaying the second gate stack and at least portions of the PFET electrodes, where the second dielectric layer and the p-channel are in compressive stress, where the compressive stress is imparted by the second dielectric layer onto the p-channel.

The invention further discloses a method for producing a circuit structure. The method includes: in the fabrication of an NFET, implementing a first gate insulator including a first high-k dielectric, where an n-channel underlies the first gate insulator, where the n-channel is hosted in a single crystal Si based material, in the fabrication of the NFET further implementing a first gate stack including a first layer of the gate metal and a cap layer, where the first high-k dielectric is in direct contact with the cap layer, further implementing NFET electrodes, including a first electrode, adjoining the n-channel and being capable of electrical continuity with the n-channel. The method further includes in the fabrication of a PFET, implementing a second gate insulator including a second high-k dielectric, where a p-channel underlies the second gate insulator, where the p-channel is hosted in the single crystal Si based material, in the fabrication of the PFET further implementing a second gate stack including a second layer of the gate metal, where the second high-k dielectric is in direct contact with the second layer of the gate metal, further implementing PELT electrodes, including a second electrode, adjoining the p-channel and being capable of electrical continuity with the p-channel. The method further includes depositing a single layer of the gate metal over the NFET and the PELT, patterning the first layer of the gate metal and the second layer of the gate metal from the single common layer of the gate metal, disposing the first electrode and the second electrode in a butted relation with each other, overlaying the first gate stack and at least portions of the NFET electrodes with a first dielectric layer, and exposing the NFET and the PELT to oxygen, where oxygen reaches the second high-k dielectric of the second gate insulator, and causes a predetermined shift in the threshold voltage of the PELT device, while due to the first dielectric layer oxygen is prevented from reaching the first high-k dielectric of the first gate insulator.

### BRIEF DESCRIPTION OF THE DRAWINGS

These and other features of the present invention will become apparent from the accompanying detailed description and drawings, wherein:

FIG. 1 shows a schematic cross section of a circuit structure according to an embodiment of the present invention, including compressive and tensile dielectric layers, metal containing gates, high-k dielectrics, and butted electrodes;

FIG. 2A shows a schematic cross section of an initial state of the processing for embodiments of the present invention;

FIG. 2B shows a schematic cross section of a stage in the processing after gate metal deposition, and involving gate patterning;

FIG. 3 shows a schematic cross section of a state of the processing for embodiments of the present invention where gate stacks and electrodes have already been formed;

FIG. 4 shows a schematic cross section of a following stage in the processing of embodiments of the present invention where spacers have been removed;

FIG. 5 shows a schematic cross section of a stage in the processing of embodiments of the present invention where a an oxygen blocking dielectric layer has been deposited, and the structure is exposed to oxygen; and

FIG. 6 shows a symbolic view of a processor containing at least one CMOS circuit according to an embodiment of the present invention.

### DETAILED DESCRIPTION OF THE INVENTION

It is understood that Field Effect Transistor-s (FET) are well known in the electronic arts. Standard components of a FET are the source, the drain, the body in-between the source and the drain, and the gate. The body is usually part of a substrate, and it is often called substrate. The gate is overlaying the body and is capable to induce a conducting channel in the body between the source and the drain. In the usual nomenclature, the channel is hosted by the body. The gate is separated from the body by the gate insulator. There are two type of FET devices: a hole conduction type, called PFET, and an electron conduction type, called NFET. Often, but exclusively, PFET and NFET devices on the same chip are wired into CMOS circuits. A CMOS circuit contains at least one PFET and at least one NFET device. In manufacturing, or processing, when NFET and PFET devices are fabricated together on the same chip, one is dealing with CMOS processing and the fabrication of CMOS structures.

In FET operation an inherent electrical attribute is the threshold voltage. When the voltage between the source and the gate exceeds the threshold voltage, the FETs are capable to carry current between the source and the drain. Since the threshold is a voltage difference between the source and the gate of the device, in general NFET threshold voltages are positive values, and PFET threshold voltages are negative values. Typically, two threshold voltages are considered in the electronic art: the low voltage threshold, and the saturation threshold. The saturation threshold, which is the threshold voltage when a high voltage is applied between the source and the drain, is lower than the low voltage threshold. Usually, at any given point in the technology's miniaturization, higher performance devices have lower thresholds than the, possibly more power conscious, lower performance devices.

As FET devices are scaled to smaller size, the traditional way of setting threshold voltage, namely by adjusting body and channel doping, looses effectiveness. The effective workfunction of the gate material, and the gate insulator properties are becoming important factors in determining the threshold of small FETs. Such so called small FETs have typically gate lengths less than 50 nm, and operate in the range of less than about 1.2V. The direction of performance driven technology is toward the use of metallic gates and high-k dielectric for gate insulators. However, the optimal combination from a performance, or processing point of view, of a particular metal gate, and a particular high-k dielectric in the gate insulator, might not lead to optimal threshold values for both NFET and PFET devices.

It is know that exposing a gate dielectric which comprises a high-k material to oxygen, can result in shifting device thresholds in a direction which is the same as if one moved the gate workfunction toward the p⁺ silicon workfunction. This results in lowering the PFET threshold, namely, making it a smaller negative voltage, and raising the NFET threshold, namely making it a larger positive voltage. It is preferable to carry out such an oxygen exposure at relatively low temperatures, and it is also preferable that no high temperature processing should occur afterwards. Accordingly, such a threshold shifting operation should occur late in the device fabrication, typically after the source and the drain have been activated. This requirement means that one has to expose the high-k material in the gate dielectric at a point in the fabrication process when substantially most of the processing has already been carried out, for instance, the gate, and gate sidewalls are all in place, and the gate insulator is shielded under possibly several layers of various materials. However, there may be a path for the oxygen to reach from the environs to the gate insulator. This path is through oxide, SiO₂, based materials. Oxide typically is the material of liners. Liners are thin insulating layers which are deposited conformally essentially over all of the structures, in particular over the gates and the source/drain regions. Use of liners is standard practice in CMOS processing. From the point of view of adjusting the threshold of the device, the property of interest is that the liner would be penetrable by oxygen. Indeed, such threshold shifts due to oxygen diffusion through liners, are known in the art, for instance: “2005 Symposium on VLSI Technology Digest of Technical Papers, Pg. 230, by E. Cartier” At the stage after the source electrode and the drain electrode have already been fabricated, additional layers, so called offset spacers, may further separate a gate insulator from the environment. As known in the art, offset spacers are usually on the side of the gate, fulfilling the same role for source/drain extension and halo implants, as the regular spacers fulfill in respect to the deeper portions of the source/drain junctions. Offset spacers may typically also be fabricated from oxide. Consequently, if a FET is exposed to oxygen, when a liner and an offset spacer are covering the gate, the oxygen may reach the gate insulator within a short time, measured in minutes our hours. However, in any given particular embodiment of FET fabrication there may be additional layers, or fewer layers, covering the gate after the source/drain fabrication, but as long as they do not block oxygen, they are not forming an obstacle for adjusting the threshold by oxygen exposure.

It would be preferable if the thresholds of the different types of devices could be adjusted individually, meaning, one would desire to use threshold tuning techniques, such as the oxygen exposure, in a manner that the threshold of one type device becomes adjusted without affecting the threshold of the other type of device. Embodiments of the present invention teach such a selective adjusting of a device threshold by having oxygen diffusion for one type of FET, while the other type of FET is not affected. The device not to be affected by the oxygen exposure is covered by a dielectric layer which does not permit oxygen penetration. Such an oxygen blocking dielectric layer may be of nitride (SiN). In some embodiments of the present invention the nitride layer may not only be used to block oxygen, but may be deposited under such conditions that it is in a stressed state. Such a stressed layer can impart its stressed state onto the channel of the FET. This stress in the channel results in higher device performance. After the oxygen exposure, the device with the changed threshold may also receive an appropriately stressed dielectric layer, mainly in order to improve its performance.

By using techniques which individually adjust the thresholds of NFET and PFET devices, one may tune the thresholds to correspond to a desired performance point. For high performance, low threshold voltages are selected. Low threshold voltages may be realized, if the workfunction of the gates as they appear for the channel charge carriers, take on so called band edge values. This means the NFET gate has an effective workfunction like n⁺ Si and the PFET gate has an effective workfunction like p⁺ Si.

Circuits of exemplary embodiments of the present invention, are capable of high performance due to band edge workfunction gates, and in addition, they are fabricated into dense configurations. Device layout density is achieved by employing butted junctions between NFET and PFET devices. The term butted junction is well known in the electronic arts, it means that two junctions, or in general two electrodes, are disposed side by side in direct physical contact, without an isolation region between them. Such isolation regions would usually be made of oxide. Omitting isolation regions between devices may greatly increase circuit density. Butted junctions become possible to realize in the embodiments of the present invention as a result of using the same gate metal material for both the NFET and PFET devices. The NFET and PFET gate metal layers are being patterned from the same, single, deposited layer of the gate metal.

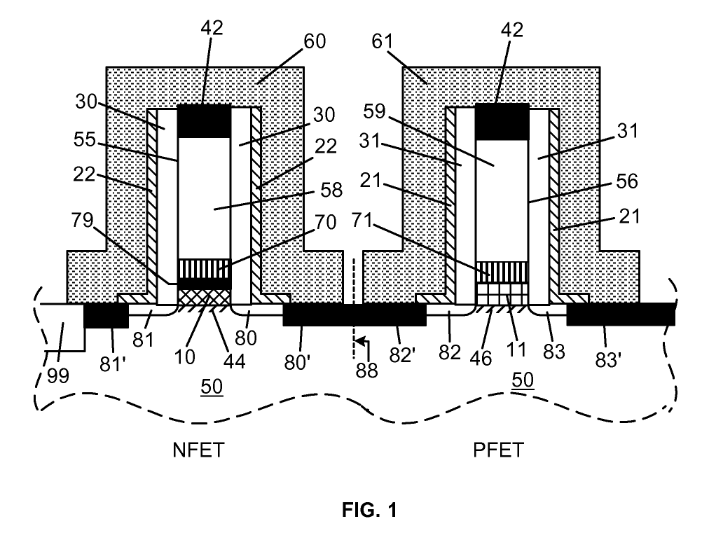

FIG. 1 shows a schematic cross section of a circuit structure according to an embodiment of the present invention, including compressive and tensile dielectric layers, gates containing the same metal, high-k dielectrics, and butted junctions Furthermore, the structure as depicted has already been exposed to oxygen, and has the thresholds of both devices optimized.

FIG. 1 depicts two devices, an NFET and a PFET, of the at least one NFET and PFET device that make up the circuit structure, typically a CMOS structure. It is understood that in addition to the elements of the embodiments of the invention the figures show several other elements, since they are standard components of FET devices, as known in the art. The device bodies 50 are typically of a single crystal Si based material. In a representative embodiment of the invention the Si based material bodies 50 are essentially single crystal Si. In exemplary embodiments of the invention the device bodies 50 are part of a substrate. The substrate may be any type known in the electronic art, such as bulk, or semiconductor on insulator (SOI), fully depleted, or partially depleted, FIN type, or any other kind. Also, substrates may have various wells of various conductivity types, in various nested positioning enclosing device bodies. These, as many other nuances are not displayed, or discussed further, as having no particular relevance for embodiments of the present disclosure. Typically devices have silicide 42 as top of the gate stacks 55, 56. As one skilled in the art would know, these elements all have their individual characteristics. Accordingly, when common indicators numbers are used in the figures of the present disclosure, it is because from the point of view of embodiments of the present invention the individual characteristics of such elements are of no major importance. The figure shows what typically may be only a small fraction of an electronic chip, for instance a processor, as indicated by the wavy dashed line boundaries.

As additional elements the devices have standard sidewall offset spacers 30, 31. For embodiments of the present invention the offset spacer material is of significance only to the extent that the offset spacer 31 pertaining to the PFET device, the one which had its threshold adjusted by oxygen exposure, is preferably penetrable by oxygen. The typical material used in the art for such spacers is oxide, satisfying the oxygen penetrability requirement. Typically the spacer of the NFET device 30 and the spacer of the PFET device 31 are fabricated during the same processing steps, and are of the same material. However, for representative embodiments of the present invention the offset spacers 30, 31 are not essential, and may not be employed at all, or may be removed before the structures are finalized.

The devices also show liners 22, 21 as known in the art. Such liners are regularly used in standard CMOS processing. The material of such liners is an oxide, typically silicon-dioxide (SiO₂). The traditional role for the liners is in the protection of the gate stacks 55, 56 and the source/drain structure regions during various processing steps, particularly during etching steps. Such liners typically have selective etching properties relative to nitride layers and silicon. The material of the PFET liner 21, typically SiO₂, allows oxygen diffusion, affording oxygen to reach the gate dielectric 11. When oxygen reaches the gate insulator 11, it can shift the threshold voltage of the PFET by a desired, predetermined amount.

The NFET device has a first gate insulator 10 and the PFET device has a second gate insulator 11. Both gate insulators comprise high-k dielectrics. Such high-k dielectrics may be ZrO₂, HfO₂, Al₂O₃, HfSiO, HfSiON, and/or their admixtures. As known in the art, their common property is the possession of a larger dielectric constant than that of the standard oxide (SiO₂) gate insulator material, which has a value of approximately 3.9. In embodiments of the present invention the gate insulator of the NFET device 10 and the gate insulator of the PFET device 11 may comprise the same high-k material, or they may have differing high-k materials. In a typical embodiment of the invention the common high-k material present in both gate insulators 10, 11 is HfO₂. Each gate insulator 10, 11, besides the high-k dielectric may have other components, as well. Typically in embodiments of the present invention a very thin, less than about 1 nm, chemically formed oxide may be present between the high-k dielectric layer and the device body 50. However, any and all inner structure, or the lack of any structure beyond simply containing a high-k dielectric, for either the first or second gate insulators 10, 11, is within the scope of the embodiments of the present invention. In exemplary embodiments of the present invention HfO₂ covering a thin chemical SiO₂ would be used as gate insulator, with an EOT of about 0.4 nm to 1.2 nm.

The first gate stack 55 of the NFET device and of the second gate stack 56 of the PFET device in typical embodiments of the present invention are multilayered structures. They usually include silicon portions 58, 59 in polycrystalline and possibly also in amorphous forms. The top of the gates usually consist of silicide layers 42. In determining the device threshold those portions of the gate stacks 55, 56 are of most significance that are near, or in contact with, the high-k material of the gate insulators 10, 11.

The NFET device was processed in such manner that oxygen was prevented from reaching the first gate insulator 10. Accordingly, the threshold of the NFET device is fixed by the interactions of the first gate insulator 10 and the layers in the first gate stack 55 adjacent to the insulator. The first gate stack 55 of the NFET device contains at least a first layer of the gate metal 70 and a cap layer 79. The first layer of the gate metal 70 may be selected from a variety of known suitable metals. The effective work function of the gate may be adjusted by the cap layer 79. Such cap layers are known in art, presented, for instance, by V. Narayanan et al, IEEE VLSI Symposium p. 224, (2006). The cap layer 79 may contain materials form Group IIA and/or Group IIIB of the periodic table. In representative embodiments of the invention the cap layer 79 may contain lanthanum (La), which under proper treatment may yield the desired threshold value. In a typical embodiments of the present invention the first high-k dielectric of the first gate insulator 10 is in direct contact with the cap layer 79, and the opposite side of the cap layer 79 is in direct contact with the first layer of the gate metal 70.

Representative embodiments of the present invention are aiming for high performance circuits, chips, and processors. Accordingly, the FET devices have to be enabled for fast switching, and to conduct large currents. Such aims are served by fabricating devices with low thresholds. With the combination of suitably selected first layer of the gate metal 70, and cap layer 79, and suitable processing conditions, the threshold of the NFET device can be adjusted to a wide range of values, including those needed for high performance operation. In representative embodiments of the present invention the NFET the saturation threshold voltage would be less than about 0.4 V, with a preferred range of between about 0.1 V and 0.3 V.

The PFET device usually has no cap layer, and the second layer of the gate metal 71 of the second gate stack 56 is in direct contact with the second high-k dielectric of the second gate insulator 11. The final adjustment of the threshold of the PFET device occurred by exposing the second high-k dielectric of the second gate insulator 11 to oxygen. Typically, such an oxygen exposure shifts the threshold of the effective workfunction of the gate to become more like p⁺ silicon. The saturation threshold voltage of the PFET would be a smaller negative value than about −0.4 V, with a preferred range of between about −0.1 V and −0.3 V.

In representative embodiments of the present invention the first high-k dielectric of the first gate insulator 10 and second high-k dielectric of the second gate insulator 11 are fabricated from the same material. In exemplary embodiments this same material may be HfO₂. In alternate embodiments the selection may be to fabricate either the NMOS or the PMOS high-k dielectric from HfO₂.

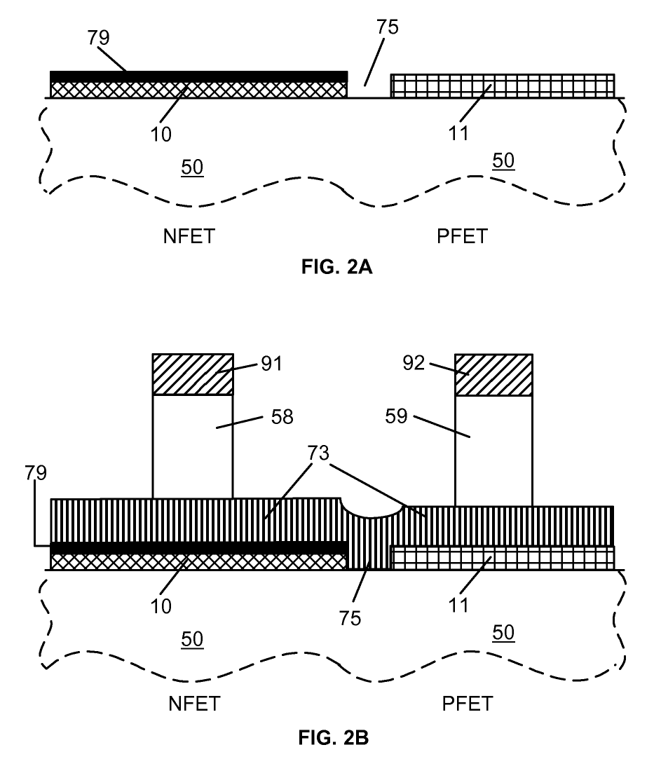

The NFET gate stack 55 includes the first layer of the gate metal 70, and the PFET gate stack 56 includes the second layer of the gate metal 71. The gate metal layers 70, 71 of the two type of devices are fabricated of the same metal, and during manufacturing the gate metal layers 70, 71 have been deposited simultaneously, forming portions of the same, single, blanket deposited, metal layer. After the deposition of the same common metal layer, 73 in FIG. 2B, the first layer of the gate metal 70, and the second layer of the gate metal 71 underwent patterning and etching, thus fulfilling their roles as parts of the gate stacks 55, 56. It exemplary embodiment of the present invention the common gate metal material may be TiN. However, other gate metals may also be considered, such as W, Mo, Mn, Ta, TaN, WN, Ru, Cr, Ta, Nb, V, Mn, Re and their mixtures, as well.

As the consequence of patterning the first and second layers of the gate metal 70, 71 from a common single deposited metal layer 73, one may be capable, as will be discussed later in relation with the fabrication methods, of fabricating butted junctions, or in general electrodes, between the NFET and PFET devices. The term “butted junction” is well known in the electronic arts, it means that two electrodes, such as the source/drain junctions from adjacent PFET and NFET devices, are disposed side by side in direct physical contact, without isolation region between them. Without the isolation regions the circuit density can be higher than without isolation regions, since no, or less, chip area is used up by the isolation structures.

An alternate term for source and drain junctions are source and drain electrodes, expressing the electrical connection between the channel and the source and the drain. Also, in deeply submicron generations of FETs, the source/drain junctions and the body of the classical FETs, namely n⁺ regions forming a junction with a p-type device body for NFET, and p⁺ region forming a junction with an n-type device body, are undergoing a myriad of changes and may not resemble textbook cases. Embodiments of the present invention are not limited by any particular realization of the NFET and PFET electrodes. Any an all variations, from all metallic Shottky barrier electrodes, to the above exemplified classical junctions, to electrodes penetrating down to buried insulating layers, and odd shaped structures belonging to various FIN device bodies, are all within the scope of embodiments of the present invention. The shape and actual realization are not significant. The common element in the embodiments of the present disclosure is that NFET and PFET electrodes are being disposed in direct physical contact, without isolation region in-between them.

FIG. 1 displays, without limiting the general scope, an electrode arrangement often used in FET devices. The fully fabricated source and drain electrodes include doped semiconductor regions, directly adjoining the channel, and silicided regions for good conductivity and contact with wiring. In the figure, the silicided regions, shown in dark, penetrate deeper than the doped regions, again a typical arrangement in FETs, and shown without the intent of limitation. For all electrodes, for both sources and drains, and for both NFET and PFET, the doped part of the electrodes are given certain reference numbers, and the silicided part of the same electrode is given as the same number primed, for instance, 83 and 83′ for one of the PFET electrodes.

The NFET electrodes 80 and 80′ and 81 and 81′, including a first electrode 80, 80′, are adjoining the n-channel 44, and are capable of being in electrical continuity with the n-channel 44. PFET electrodes 82 and 82′ and 83 and 83′, including a second electrode 82, 82′, are adjoining the p-channel 46, and are capable of being in electrical continuity with the p-channel 46. Electrical current can flow between the electrodes of either of the devices, through the respective channel, when the source to gate voltage exceeds the threshold voltage value. As shown in the figure, the sides of the electrodes facing away from the channel are butted. The first electrode 80, 80′ and the second electrode 82, 82′ are butted against one another in direct physical contact. A dotted line 88 shows an imaginary boundary, which for the embodiment of the present invention, indicates where and isolation structure might usually be. If desired, isolation structures, of course, can be introduced between devices. The presented fabrication method allows the butting of electrodes, it does not necessarily requires it. As illustrated, for instance the NFET junction 81, 81′ is not butted against another junction, but is confined by an isolation structure 99, shown as an oxide shallow trench scheme, known in the art.

In typical embodiments of the present invention the nature of the circuit prescribes which of the electrodes, namely source or drain, are butted for the NFET and PFET devices. In CMOS circuit configuration the source electrodes of the PFET devices is electrically connected to the drain electrode of NFET devices. Accordingly, in a CMOS embodiment of the present invention, the first electrode 80, 80′ is a drain electrode, and the second electrode 82, 82′ is a source electrode. However, there may be differing circuits, for instance, pass-gate circuits, where butting between NFET and PFET electrodes takes on different configuration, such as, for instance, a source to source butting. All circuits where NFET and PFET devices benefit from having their electrodes in direct physical contact, independently whether they are sources or drains, are within the teaching of the present disclosure.

FIG. 1 further shows the presence of a first dielectric layer 60 overlaying the first gate stack 55 and least portions of the of the NFET electrodes 80, 80′, and 81, 81′. At the depicted stage of the fabrication there is also a second dielectric layer 61 overlaying the second gate stack 56 and least portions of the PFET electrodes 82, 82′, and 83, 83′.

Both dielectric layers 60, 61 may be in a state of stress, but preferably of opposite signs. The first dielectric layer 60 may be in tensile stress, and the second dielectric layer 61 may be in compressive stress. As one skilled in the art knows, the stress in the dielectric layers 60, 61 imparts a stress to the underlying electrodes and substrate 50. As also known in the art, the state of the stress in the channel regions is the same as in the overlaying dielectric layers. Accordingly, since the first dielectric layer 60 is in tensile stress, it imparts onto the n-channel 44 a tensile stress, and since the second dielectric layer 61 is in compressive stress, the it imparts onto the p-channel 46 a compressive stress.

Inducing stress of a desirable kind in channels of FET devices by the use of stressed dielectric layers has been known in the art. The properties of charge transport in Si based materials is such that FET performance improves if an n-channel is under tensile stress, and a p-channel is under compressive stress. As discussed above, in preferred embodiments of the present invention this performance enhancing pattern is followed.

In exemplary embodiments of the present invention both the first 60 and the second 61 dielectric layers are nitride (SiN) layers, which can be deposited as either under compressive, or under tensile stress. The thickness of the stressed nitride layers are usually about between 20 nm and 150 nm.

It is understood that FIG. 1, as all figures, is only a schematic representation. As known in the art, there may be many more, or less, elements in the structures than presented in the figures, but these would not affect the scope of the embodiments of the present invention.

Further discussion and figures may present only those processing steps which are relevant in yielding the structure of FIG. 1. Manufacturing of NFET, PFET, and their circuit structures, such as CMOS, is very well established in the art. It is understood that there are a large number of steps involved in such processing, and each step might have practically endless variations known to those skilled in the art. It is further understood that the whole range of known processing techniques are available for fabricating the disclosed device structures, and only those process steps will be detailed that are related to embodiments of the present invention.

FIGS. 2A and 2B show initial stages of the circuit structure fabrication and illustrate the connection between using a single common layer as the metal gate material for both type of devices, and the butting of the electrodes.

FIG. 2A shows a schematic cross section of an initial state of the processing for embodiments of the present invention. The gate dielectric layers 10, 11 for NFET and for PFET have already deposited, together with the cap layer 79 on the NFET side. To reach this stage, as known in the art, there are several block level masking steps are involved in defining and aligning various layers with the appropriate device structures. Alignment of masks always have tolerances. Due to such masking tolerances, inevitably a situation as shown on FIG. 2A will arise, where the dielectric layered structures have a gap 75 between them, leaving the substrate material, typically Si, or Si based, exposed. At other places, on the chip it might happen that the two deposited dielectric layered structures overlap at their boundaries.

FIG. 2B shows a schematic cross section of a stage in the processing after gate metal deposition, and involving gate patterning. The fabrication of the circuit structure includes depositing a single layer of the gate metal 73 over the NFET and the PFET. Since this is a single, common, layer of metal 73 it does not need block level masking, it is blanket deposited everywhere. In this manner it is assured that it is filling in the gap 75 which might have been left between the dielectric layer. If one were to use two different metal layers as the NFET and PFET gate metals, again because of masking tolerances, there would be no assurance that the gap 75 is not left open. An open gap 75 may be ruinous during further processing, because there is no known metal/Si differential etching process in the art, in the sense that it would etch the metal layer 73, but would not etch the substrate 50. Etching of the metal is needed as part of the patterning of the actual gate stacks for the devices. In an alternative scenario if one were to use two different metal layers as the NFET and PFET gate metals, there could be an overlap left of the metal layers. Such an overlap may lead to incomplete removal of metals in the overlapped region, again resulting in fatal defects.

In FIG. 2B masking layers, 91 and 92 have been formed to define the gate stack locations. In the figure the masking layers 91, 92 are displayed only symbolically, since as known in the art they too might be complicated layered structures including soft and hard layers. FIG. 2B shows the stage where various parts of the gate stacks 58 and 59, usually including silicon in polycrystalline and possibly in amorphous forms, have already etched out. The stage shown in FIG. 2B is to be followed by steps for etching the metal layer 73, to fully define the first and second gate stacks 55, 56. Such an etching step may include HBr or Cl Reactive Ion Etch (RIE) chemistries, which are standard processes used to etch metals. However, these etch chemistries are not selective to Si. In this way the fabrication included the patterning of the first layer of the gate metal 70 and the second layer of the gate metal 71 from the single layer of the gate metal 73. Since, the gap 75 is filled by the metal layer 73, it etches at the same rate as the gate stacks and no deep damaging penetration occurs into the substrate 50 before the etching can stop. If the gate metal for the two type of devices would be different, and due to the discussed additional masking the gap 75 would not be necessarily filled, the only way that one could assure that no damage occurs to the circuit from etching into the substrate 50 is to provide for an isolation structure between the two devices, where the gap 75 might fall. This is the reason that butting of the electrodes is tied into the nature of the NFET/PFET gate metal, and such butting is a novel process in the art of metal gates.

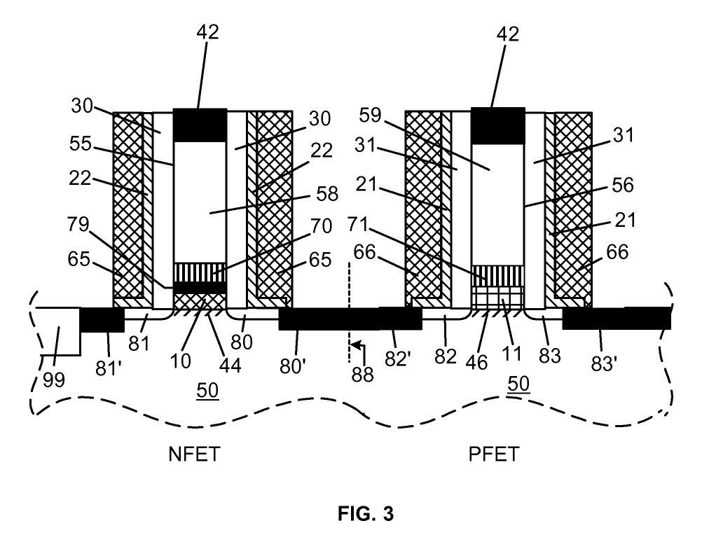

FIG. 3 shows a schematic cross section of a state of the processing for embodiments of the present invention where gate stacks and source/drain electrodes have already been formed. Following the patterning of the gate stacks, the NFET and PFET devices have reached the depicted stage in the fabrication by the use of processing steps known in the art. The threshold for the NFET device has been set with the help of the cap layer 79. Spacers 65, 66 are shown because they are elements, as know in the art, involved in source/drain fabrication and the silicidation of electrodes 80′, 81′, 82′, 83′, and of the gates 42. The spacers 65, 66 typically are made of nitride. The connecting electrodes 80, 80′ and 82, 82′ have been processed to be in direct physical contact, in so called butted relation across a device dividing line 88.

The electrodes of the devices have already been through the high thermal budget activation process. In FET processing, typically the largest temperature budgets, meaning temperature and time exposure combinations, are reached during source/drain electrodes fabrication. Since the sources and drains have already been fabricated, for the structure of FIG. 3 such high temperature fabrication steps have already been performed, and the structure will not have to be exposed to further large temperature budget treatment. From the perspective of embodiments of the present invention, exposure to a high temperature budget means a comparable heat treatment as the one used in the source/drain fabrication.

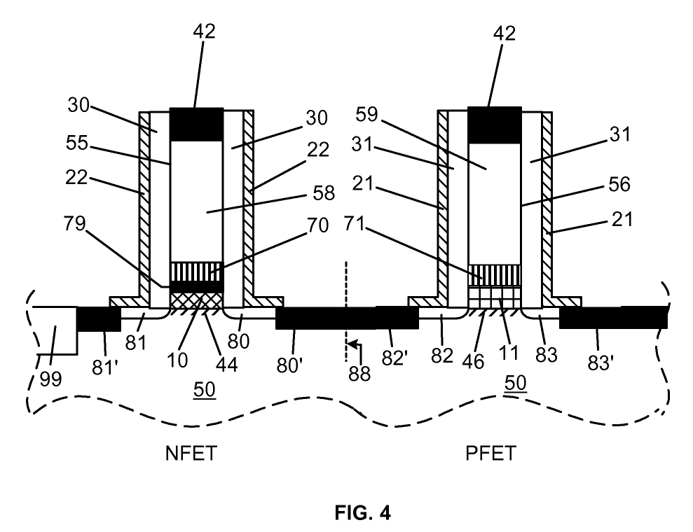

FIG. 4 shows a schematic cross section of a following stage in the processing of embodiments of the present invention, where spacers have been removed. In standard FET fabrication the spacers 65, 66 would remain in place through the many following processing steps. In embodiments of the present invention, however, the final threshold adjustment by oxygen exposure of the PFET device is yet to be done. The spacer for the PFET device 66, which is made of nitride, would block oxygen penetration to the high-k material of the gate dielectric 11. Accordingly, the spacer of the PFET device may have to be removed. The spacer of the NFET device 65 in principle could stay as a barrier against oxygen penetration. However, embodiments of the present invention call for high performance devices, which preferably are under appropriate stress. In representative embodiments of the present invention the dual roles of protecting the gate dielectric 10 of the NFET device, and of providing stress for high performance, may be combined into one. Accordingly, both spacers 65, 66 are being removed. The removal is done by etching in manners known in the art. For instance, glycerated buffered hydrofluoric acid with ratios of 5:1:1.6 etches nitride selectively versus silicon, oxide, and metal, which materials may be exposed on the wafer surface while the nitride is being etched.

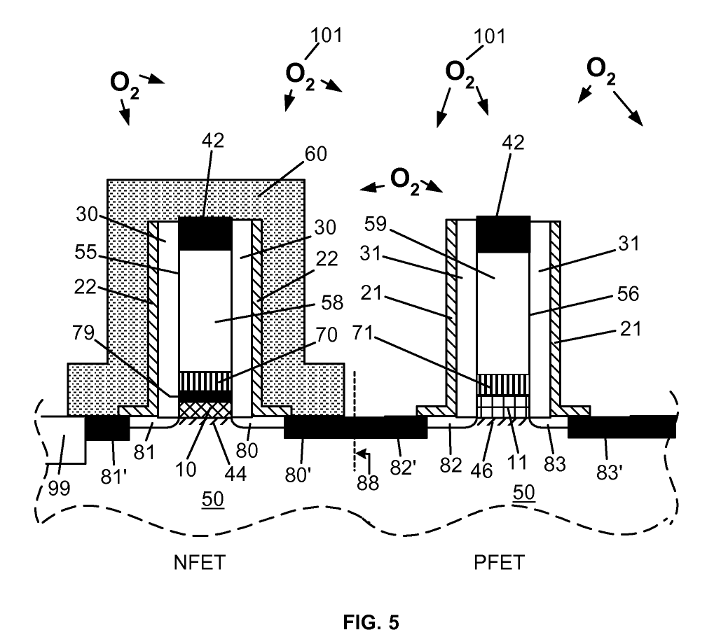

FIG. 5 shows a schematic cross section of a stage in the processing of embodiments of the present invention, where a an oxygen blocking dielectric layer has been deposited, and the structure is exposed to oxygen. After the application of proper blocking masks, as known in the art, the NFET device is overlaid by a first dielectric layer 60 covering the first gate stack 55 and at least portions of the NFET electrodes 80, 80′, 81, 81′. The first dielectric layer 60 and the n-channel 44 are in tensile stress, which tensile stress is imparted by the first dielectric layer 60 onto the n-channel 44. Also, the first dielectric layer 60 is so selected to be a blocker against oxygen penetration. In typical embodiments of the present invention the first dielectric layer 60 is a nitride (SiN) layer. FIG. 5 shows the step of oxygen exposure 101, as well. This exposure may occur at low temperature at about 200° C. to 350° C. by furnace or rapid thermal anneal. The duration of the oxygen exposure 101 may vary broadly from approximately 2 minutes to about 150 minutes. For the duration of the exposure oxygen is blocked by the first dielectric layer 60 from penetrating to the first gate insulator 10, but oxygen is capable of penetrating to the second gate insulator 11. The amount of threshold shift for the PFET device depends on the oxygen exposure parameters, primarily on the temperature and duration of the procedure. In exemplary embodiments of the present invention the size of the threshold shift is so selected that the final threshold is suited for high performance applications, the effective workfunction of the gate stack 56 being similar to that of p⁺ Si.

After the oxygen exposure step, the PFET device is overlaid with a second dielectric layer 61, in compressive stress, which is imparted to the p-channel 46. In exemplary embodiments of the present invention the second dielectric layer 60 is a nitride (SiN) layer. With the second dielectric layer 61 in place, one arrives to the structure as displayed in FIG. 1, and discussed in reference to FIG. 1.

Finally, the circuit structure, and its wiring, may be completed with standard steps known to one skilled in the art.

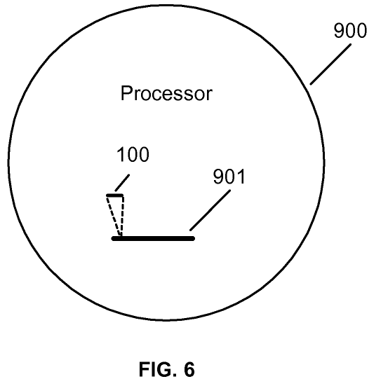

FIG. 6 shows a symbolic view of a processor containing at least one CMOS circuit according to an embodiment of the present invention. Such a processor 900 has at least one chip 901, which contains at least one circuit structure 100, with at least one NFET and one PFET having high-k gate dielectrics, gate stacks comprising a common gate metal, a cap layer in one of the gates, and butted junctions. The circuits may also have and stressed dielectric layers covering the NMOS and CMOS devices, as described in reference to FIGS. 1-5. The saturation thresholds of the FETs are optimized for high performance. The processor 900 may be any processor which can benefit from embodiments of the present invention, which yields high performance circuits. Representative embodiments of processors manufactured with embodiments of the disclosed structure are digital processors, typically found in the central processing complex of computers; mixed digital/analog processors, typically found in communication equipment; and others.

Many modifications and variations of the present invention are possible in light of the above teachings, and could be apparent for those skilled in the art. The scope of the invention is defined by the appended claims.

We claim:

1. A circuit structure, comprising:
at least one NFET and at least one PFET;
wherein said NFET comprises:
an n-channel hosted in a single crystal Si based material;
a first gate stack comprising a first layer of a gate metal and a cap layer;
a first gate insulator comprising a first high-k dielectric, wherein said first high-k dielectric is in direct contact with said cap layer;
NFET electrodes, including a first electrode, adjoining said n-channel, and capable of being in electrical continuity with said n-channel;
wherein said PFET comprises:
a p-channel hosted in said single crystal Si based material;
a second gate stack comprising a second layer of said gate metal;
a second gate insulator comprising a second high-k dielectric, wherein said second high-k dielectric is in direct contact with said second layer of said gate metal;
PFET electrodes, including a second electrode, adjoining said p-channel, and capable of being in electrical continuity with said p-channel; and
wherein said first electrode and said second electrode are butted against one another in direct physical contact.

2. The circuit structure of claim 1, further comprising:
a first dielectric layer overlaying said first gate stack and at least portions of said NFET electrodes, wherein said first dielectric layer and said n-channel are in tensile stress, wherein said tensile stress is imparted by said first dielectric layer onto said n-channel; and
a second dielectric layer overlaying said second gate stack and at least portions of said PFET electrodes, wherein said second dielectric layer and said p-channel are in compressive stress, wherein said compressive stress is imparted by said second dielectric layer onto said p-channel.

3. The circuit structure of claim 2, wherein said first dielectric layer and said second dielectric layer are both composed essentially of SiN.

4. The circuit structure of claim 1, wherein said gate metal is TiN.

5. The circuit structure of claim 1, wherein said first high-k dielectric and said second high-k dielectric are of a same material.

6. The circuit structure of claim 5, wherein said same material is essentially HfO₂.

7. The circuit structure of claim 1, wherein at least one of said first high-k dielectric and said second high-k dielectric is composed essentially of HfO₂.

8. The circuit structure of claim 1, wherein said single crystal Si based material is essentially pure Si.

9. The circuit structure of claim 1, wherein said first electrode is a drain electrode.

10. The circuit structure of claim 1, wherein said second electrode is a source electrode.

11. The circuit structure of claim 1, wherein said circuit structure is a CMOS structure.

12. A method for processing a circuit structure, comprising:
in an NFET, implementing a first gate insulator comprising a first high-k dielectric, wherein an n-channel underlies said first gate insulator, wherein said n-channel is hosted in a single crystal Si based material, further implementing a first gate stack comprising a first layer of a gate metal and a cap layer, wherein said first high-k dielectric is in direct contact with said cap layer, further implementing NFET electrodes, including a first electrode, adjoining said n-channel and being capable of electrical continuity with said n-channel;
in a PFET, implementing a second gate insulator comprising a second high-k dielectric, wherein a p-channel underlies said second gate insulator, wherein said p-channel is hosted in said single crystal Si based material, further implementing a second gate stack comprising a second layer of said gate metal, wherein said second high-k dielectric is in direct contact with said second layer of said gate metal, further implementing PFET electrodes, including a second electrode, adjoining said p-channel and being capable of electrical continuity with said p-channel;
depositing a single layer of said gate metal over said NFET and said PFET, and patterning said first layer of said gate metal and said second layer of said gate metal from said single layer of said gate metal;
disposing said first electrode and said second electrode in a butted relation with each other;
overlaying said first gate stack and at least portions of said NFET electrodes with a first dielectric layer; and
exposing said NFET and said PFET to oxygen, wherein oxygen reaches said second high-k dielectric of said second gate insulator, and causes a predetermined shift in the threshold voltage of said PFET device, while due to said first dielectric layer oxygen is prevented from reaching said first high-k dielectric of said first gate insulator.

13. The method of claim 12, further comprising:
overlaying said second gate stack and at least portions of said PFET electrodes with a second dielectric layer, and selecting said second dielectric layer to be in compressive stress, wherein said second dielectric layer imparts said compressive stress onto said p-channel.

14. The method of claim 13, further comprising:
selecting said first dielectric layer to be in tensile stress, wherein said first dielectric layer imparts said tensile stress onto said n-channel.

15. The method of claim 14, wherein said first dielectric layer and said second dielectric layer are both selected to be essentially SiN.

16. The method of claim 12, wherein said first high-k dielectric and said second high-k dielectric are selected to be of a same material.

17. The method of claim 16, wherein said same material is selected to be essentially of HfO₂.

18. The method of claim 12, wherein at least one of said first high-k dielectric and said second high-k dielectric is selected to be essentially of HfO₂.

19. The method of claim 12, wherein said gate metal is selected to be TiN.

20. The method of claim 12, wherein said first electrode is selected to be a drain electrode.

21. The method of claim 12, wherein said second electrode is selected to be a source electrode.

22. The method of claim 12, wherein said circuit structure is selected to be a CMOS structure.
